(19) United States
(12) Patent Application Publication
(10) Pub. No.: US 2006/0091478 A1
(43) Pub. Date: May 4, 2006

(54) Semiconductor gate structure and method for preparing the same

(75) Inventors: Cheng Che Lee, Taichung (TW); Chih Chung Chuang, Tainan (TW); Tai Yuan Chen, Changhua (TW)

Correspondence Address: OLIFF & BERRIDGE, PLC, P.O. BOX 19928, ALEXANDRIA, VA, 22320, US

(73) Assignee: PROMOS TECHNOLOGIES INC., Hsinchu (TW)

(21) Appl. No.: 10/980,165

(22) Filed: Nov. 4, 2004

(51) Int. Cl. H01L 29/06

(52) U.S. Cl. 257/388

(57) ABSTRACT

A semiconductor gate structure is described, which comprises a substrate, a gate oxide positioned on the substrate, a first conductive layer positioned on the gate oxide and a second conductive layer positioned on the first conductive layer. The second conductive layer comprises a bottom portion positioned on the first conductive layer, and an upper portion positioned on the bottom portion. The width of the bottom portion is equal to that of the first conductive layer, and one side of the upper portion is aligned to one side of the bottom potion, wherein the other side of the upper portion possesses at least a lateral concave. A bit-line contact metal is subsequently formed next to the concave.

### BACKGROUND OF THE INVENTION

(A) Field of the Invention

The present invention relates to a semiconductor gate structure and methods for preparing the same, and more particularly, to a semiconductor gate structure capable of preventing the gate conductor from forming short circuit with the bit-line contact metal and methods for preparing the same.

(B) Description of the Related Art

Metal oxide semiconductor (MOS) transistor generally consists of a metal layer, a silicon oxide layer and a silicon substrate. Because of the poor adhesion between the metal layer and the silicon oxide layer, polysilicon is widely used to replace the metal layer as the conductive layer in the semiconductor gate structure of the MOS transistor. However, the conductivity of polysilicon cannot meet the requirement of higher conductivity from the advanced MOS transistor. One of the widely used solutions is to form a tungsten silicide layer on the polysilicon, wherein the high conductivity of tungsten improves the overall conductivity of the semiconductor gate structure.

FIG. 1(a) to FIG. 1(c) illustrate the method for preparing a gate conductor 5 according to the prior art. A plurality of separate semiconductor gate structures are formed on a substrate 2, and a dielectric layer 12 is then formed on the substrate 2, wherein each semiconductor gate structure comprises a first conductive layer 4, a second conductive layer 6, an insulation layer 8 and a spacer 10. The first conductive layer 4 and the second conductive layer 6 consist of the gate conductor 5 of the MOS transistor. A photolithographic process and an etching process are performed on the dielectric layer 12 to remove a predetermined portion of the dielectric layer 12 to form a contact window 18 (bit-line contact window) by exposing the upper surface of the substrate 2. A metal layer 14 with a predetermined thickness is deposited to cover the dielectric layer 12, the spacer 10 of the semiconductor gate structure and the substrate 2 so as to form a bit-line contact metal with a width X in the contact window 18.

The above-mentioned etching process also etches the insulation layer 8 and the spacer 10 except the dielectric layer 12. Since the etching rate of the insulation layer 8 and the spacer 10 is smaller than that of the dielectric layer 12, only a portion of the insulation layer 8 and the spacer 10 is removed during the etching process. Consequently, the etching process can form the contact window 18 between the semiconductor gate structures, and the contact window 18 is self-aligned to a contact area on the substrate 2.

The contact resistance of the metal contact prepared according to the above-mentioned process depends on the size of the contact area, i.e., the area marked by the width X, between the metal layer 14 and the substrate 2. Although extending the etching time of the etching process can increase the contact area, an improper control of the etching time tends to over-etch the dielectric layer 8 and the spacer 10 and expose the second conductive layer 6 below the insulation layer 8. The exposed portion of the second conductive layer 6 forms electrical contact with the metal layer 14 at the corner 16 and causes short circuit.

U.S. Pat. No. 5,989,987 discloses a method for preparing a self-aligned contact window. Compared with the method described in FIG. 1(a) to FIG. 1(c), U.S. Pat. No. 5,989,987 teaches to perform a full-scale etching process to remove the sides of the second conductive layer 6 so as to reduce the width of the second conductive layer 6 before the formation of the spacer 10. As the width of the second conductive layer 6 reduces, the distance between the second conductive layer 6 and the subsequently formed metal layer 14 is increased to prevent the second conductive layer 6 from forming electrical contact with the metal layer 14 at the corner 16. However, U.S. Pat. No. 5,989,987 uses the full-scale etching process to reduce the lateral width of the second conductive layer 6, which results in a dramatic increase in resistance of the gate conductor 5.

### SUMMARY OF THE INVENTION

The objective of the present invention is to provide a semiconductor gate structure capable of preventing the occurrence of short circuit between the gate conductor and the bit-line contact metal without dramatic increase of the resistance of the gate conductor and methods for preparing the same.

In order to achieve the above-mentioned objective and avoid the problems of the prior art, the present invention provides a semiconductor gate structure capable of preventing the gate conductor from forming short circuit with the bit-line contact and methods for preparing the same. The semiconductor gate structure comprises a substrate, a gate dielectric layer positioned on the substrate, a first conductive layer positioned on the gate dielectric layer and a second conductive layer positioned on the first conductive layer. The second conductive layer comprises a bottom portion positioned on the first conductive layer and a top portion positioned on the bottom portion, wherein one side of the top portion is aligned with one side of the bottom portion and the top portion includes at least one concave at the other side.

The present method for preparing a semiconductor gate structure forms a gate dielectric layer, a first conductive layer, a second conductive layer and a photoresist layer in sequence on a substrate. A photolithographic process is performed to form at least one opening in the photoresist layer, and an etching process is then performed to form at least one concave in the top portion of the second conductive layer below the opening. The etching process can be a wet etching process using an etching solution including ammonia, hydrogen peroxide and water, and is preferably performed at a temperature between 60° C. and 70° C. In addition, the etching process can be a dry etching process using an etching gas selected from the group consisting of carbon tetrafluoride and sulfur hexafluoride.

Another method for preparing a semiconductor gate structure forms a gate dielectric layer, a first conductive layer, a second conductive layer and an insulation layer having a plurality of strip-shaped openings in sequence on a substrate. A photoresist layer is formed on the insulation layer, and a photolithographic process is then performed to form at least one opening in the photoresist layer. A first etching process is performed to form at least one concave in a top portion of the second conductive layer below the opening in the photoresist layer. After the photoresist layer is removed, a second etching process is performed to remove the first conductive layer and the second conductive layer below the strip-shaped opening. A spacer is formed on sidewalls of the first conductive layer, the second conductive layer and the insulation layer, wherein the concave is filled with an insulation material for the insulation layer. A bit-line contact metal is subsequently formed at one side of the concave.

According to the present invention, a concave is formed only at a region where the second conductive layer approximates the bit-line contact metal, while the gate conductor keeps the original strip-shaped profile at the other region. Consequently, the occurrence of the short circuit originating from the electrical contact between the second conductive layer and the bit-line contact metal can be avoided, and the present invention also solves the issue of the dramatic increase of the resistance due to the full-scale reduction of the width of the gate conductor.

### BRIEF DESCRIPTION OF THE DRAWINGS

Other objectives and advantages of the present invention will become apparent upon reading the following description and upon reference to the accompanying drawings in which:

FIG. 1(a) to FIG. 1(c) illustrate the method for preparing a gate conductor according to the prior art;

FIG. 2(a) to FIG. 2(h) illustrate a method for preparing a semiconductor gate structure according to one preferable embodiment of the present invention;

FIG. 3 is a schematic diagram of the semiconductor gate structure according to the present invention; and

FIG. 4(a) to FIG. 4(e) illustrate another method for preparing a semiconductor gate structure according to the present invention.

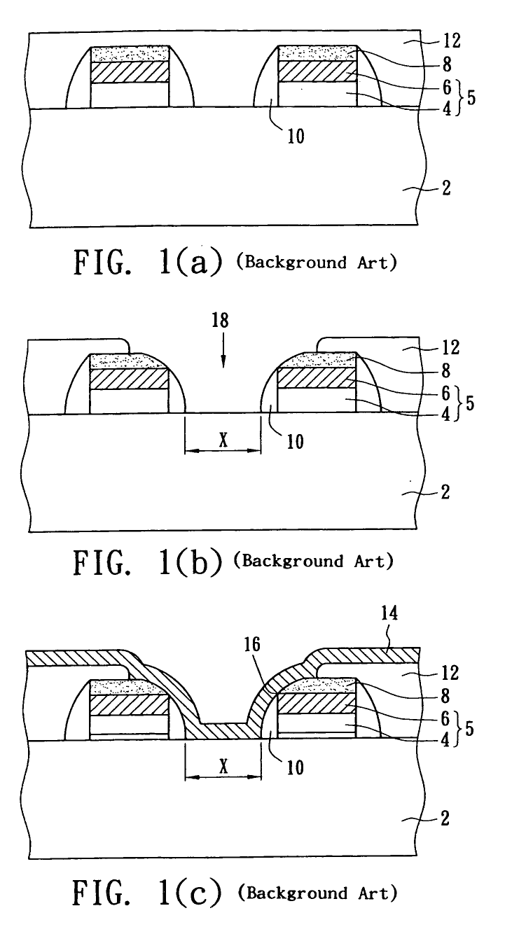

### DETAILED DESCRIPTION OF THE INVENTION

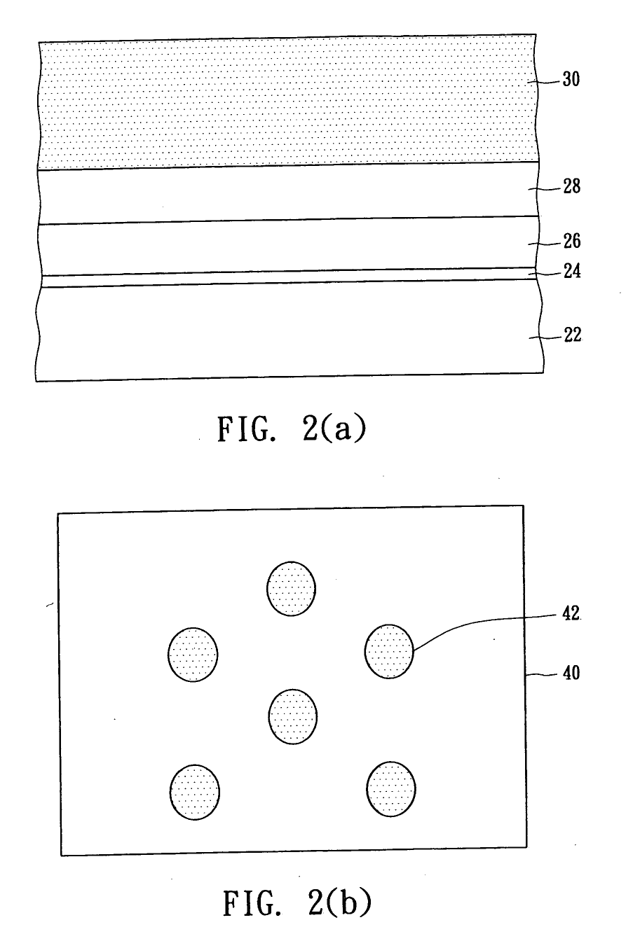

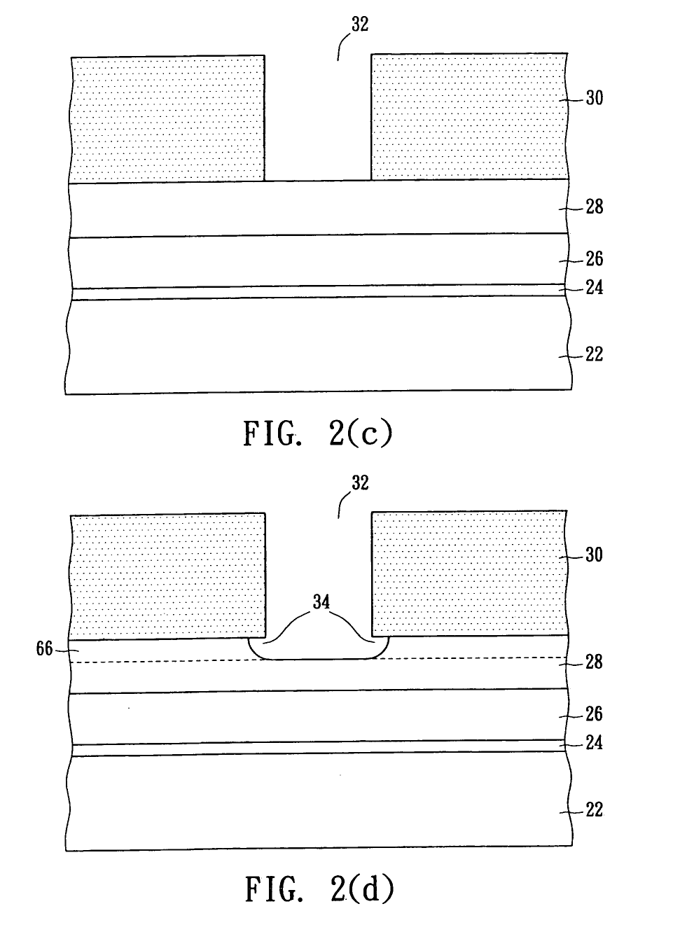

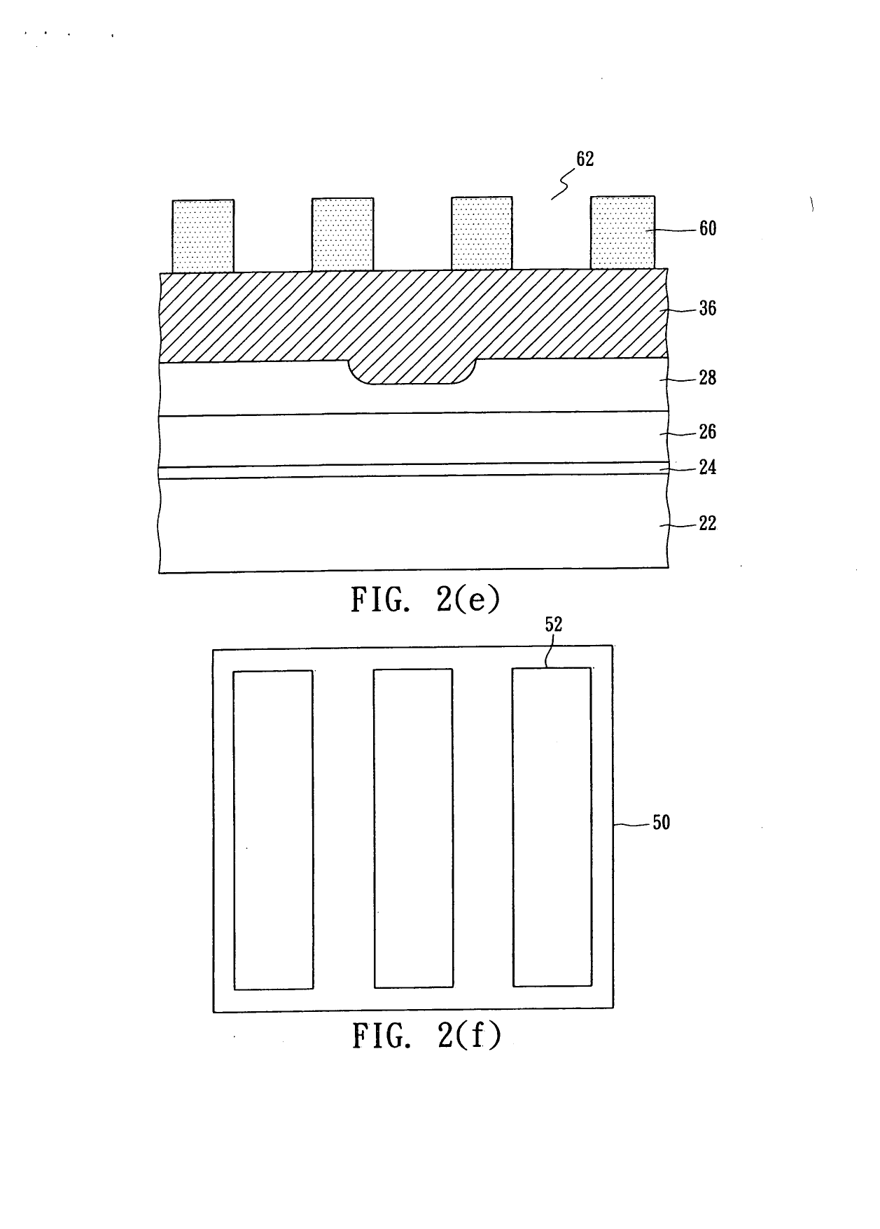

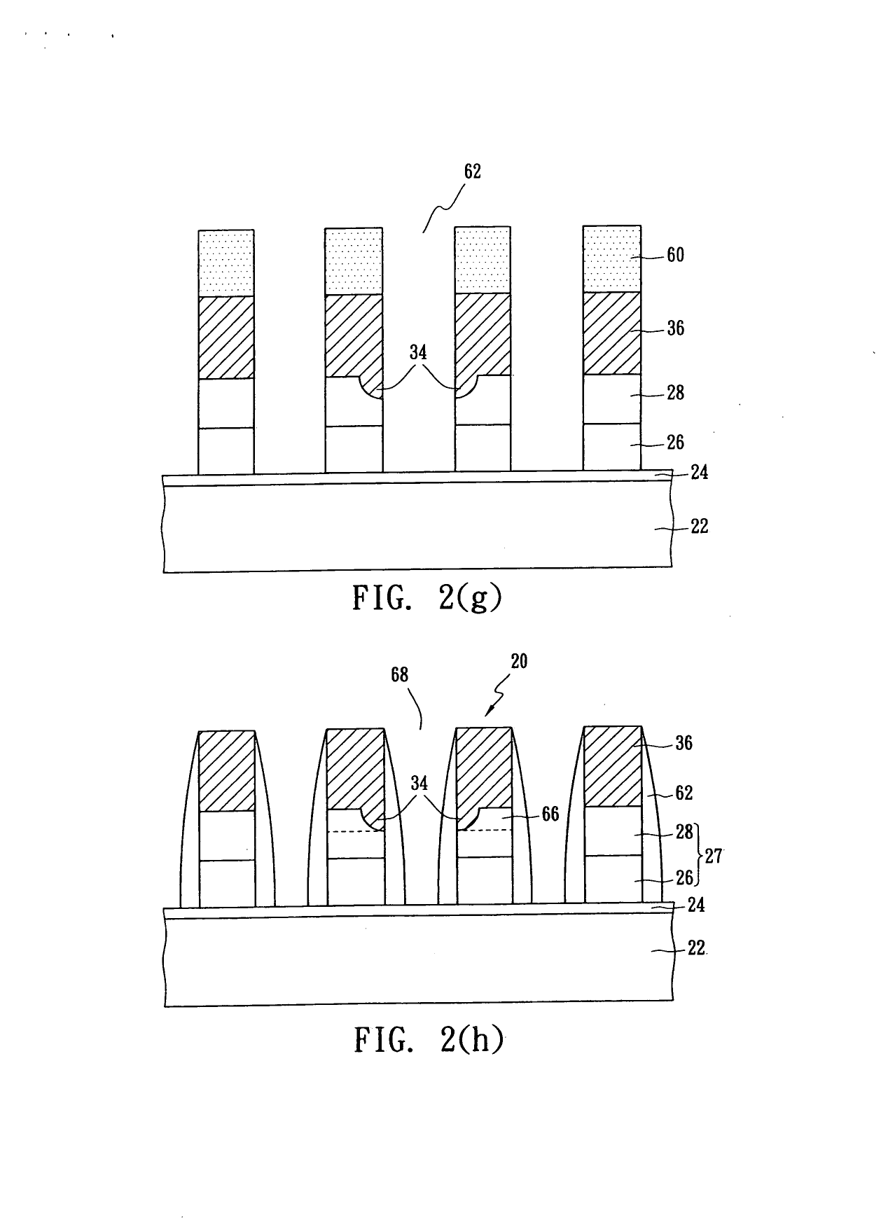

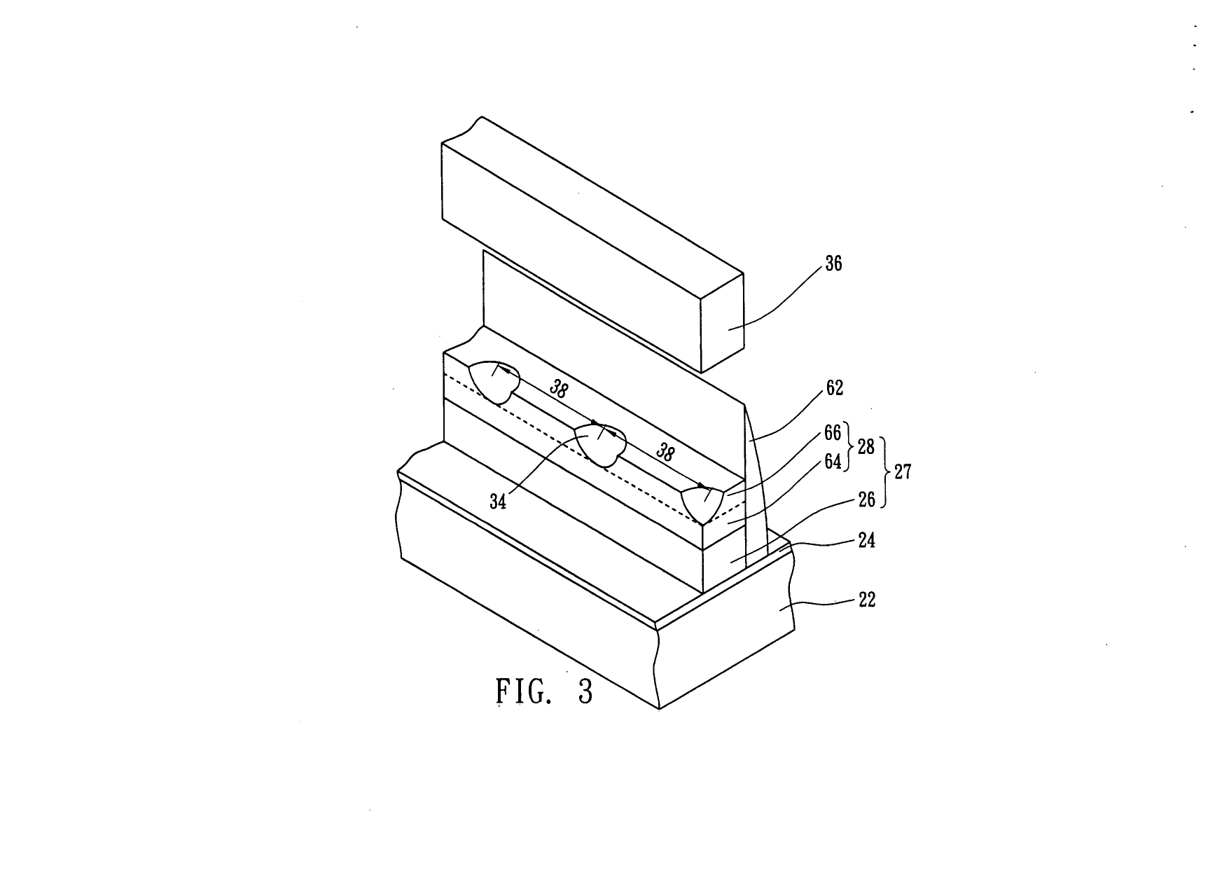

FIG. 2(a) to FIG. 2(h) illustrate a method for preparing a semiconductor gate structure according to one preferable embodiment of the present invention. As shown in FIG. 2(a), the present invention first forms a gate dielectric layer 24, a first conductive layer 26, a second conductive layer 28 and a photoresist layer 30 in sequence on a substrate 22. The first conductive layer 26 can be made of polysilicon, and the second conductive layer 28 can be made of tungsten suicide.

FIG. 2 (b) is a top view of a bit-line contact window mask 40. The bit-line contact window mask 40 has a plurality of patterns 42, and a plurality of openings 32 can be formed in the photoresist layer by a photolithographic process using the bit-line contact window mask 40, as shown in FIG. 2(c). The position of the opening 32 corresponds to the pattern 42, wherein only an opening 32 is shown in FIG. 2(c) for clarity.

Referring to FIG. 2(d), an etching process is performed to remove a portion of the second conductive layer 28 from a top portion 66. The etching process can be a wet etching process using an etching solution including ammonia, hydrogen peroxide and water, and performed at a temperature between 60° C. and 70° C. Preferably, the wet etching process is performed substantially at 65° C. In addition, the etching process can be a dry etching process using an etching gas selected from the group consisting of carbon tetrafluoride and sulfur hexafluoride. In addition to vertically remove the second conductive layer 28 right below the opening 32, the etching process also laterally etch the top portion 66 of the second conductive layer 28 below the photoresist layer 30 and nearby the opening 32 to form a concave 34 nearby the opening 32 since etching process is an isotropic etching process.

Referring to FIGS. 2(e) and 2(f), after the photoresist layer 30 is removed, an insulation layer 36 is formed on the second conductive layer 28 and a photoresist layer 60 is formed on the insulation layer 36, wherein the concave is filled with an insulation material consisting of the insulation layer 36. A photolithographic process is performed using a gate conductor mask 50 as shown in FIG. 2(f) to form a plurality of strip-shaped opening 62 in the photoresist layer 60. The gate conductor mask 50 has a plurality of strip-shaped patterns 52, and the strip-shaped opening 62 in the photoresist layer 60 corresponds to the strip-shaped pattern 52.

Referring to FIG. 2(g) and FIG. 2(h), an etching process is performed to remove a portion of the insulation layer 36, the second conductive layer 28 and the first conductive layer 26 right below the strip-shaped opening 62. The photoresist layer 60 is then removed, and a spacer 62 is subsequently formed on sidewalls of the first conductive layer 26, the second conductive layer 28 and the insulation layer 36 to complete the semiconductor gate structure 20 according to the present invention.

The position of the concave 34 is defined by the bit-line contact window mask 40, and the opening between two concaves 34 is a bit-line contact window 68, as shown in FIG. 2(h). The first conductive layer 26 and the second conductive layer 28 constitute a gate conductor 27. The concave 34 is positioned at the top portion 66 of the second conductive layer 28 to increase the distance between the gate conductor 27 and a contact metal subsequently formed in the bit-line contact window 68. Consequently, the short circuit originating from the electrical contact between the gate conductor 27 and the contact metal in the bit-line contact window 68 can be avoided.

FIG. 3 is a schematic diagram of the semiconductor gate structure 20 according to the present invention. For the purpose of clarity, the insulation material filling the concave 34 and the spacer 62 at the left side are not shown in FIG. 3, and the insulation layer 36 is moved upward to show the concaves 34. The second conductive layer 28 can be divided into a bottom portion 64 positioned on the first conductive layer 26 and a top portion 66 positioned on the bottom portion 64. The width of the bottom portion 64 is substantially equal to that of the first conductive layer 26, the right side of the top portion 66 is aligned with the right side of the bottom portion 64, and there are several concaves 34 positioned at the left side of the top portion 64. The plurality of concaves 34 are discontinuous, the distance between two concaves 34 is substantially the same, and the bit-line contact window 68 is positioned at the left side of the concaves 34. Since the concaves 34 increase the distance between the gate conductor 27 and the contact metal subsequently formed in the bit-line contact window 68, the present invention can avoid the occurrence of the short circuit originating from the electrical contact between the gate conductor 27 and the contact metal in the bit-line contact window 68. In addition, the present invention forms the concave 34 only at a region where the gate conductor 27 approximates the bit-line contact window 68, while the gate conductor 27 keeps the original strip-shaped profile at the other region. Consequently, the resistance of the gate conductor 27 does not be dramatically increased due to the formation of the concave 34 according to the present invention.

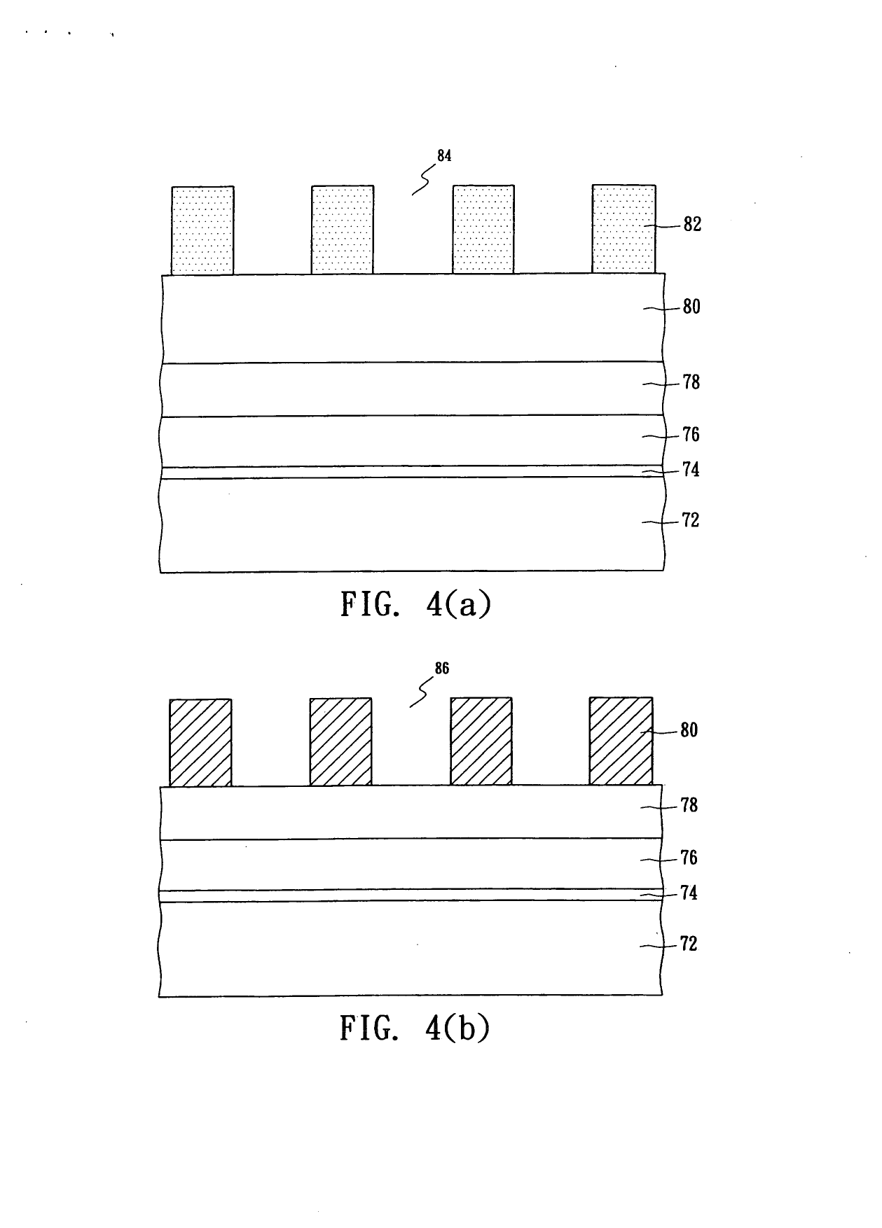

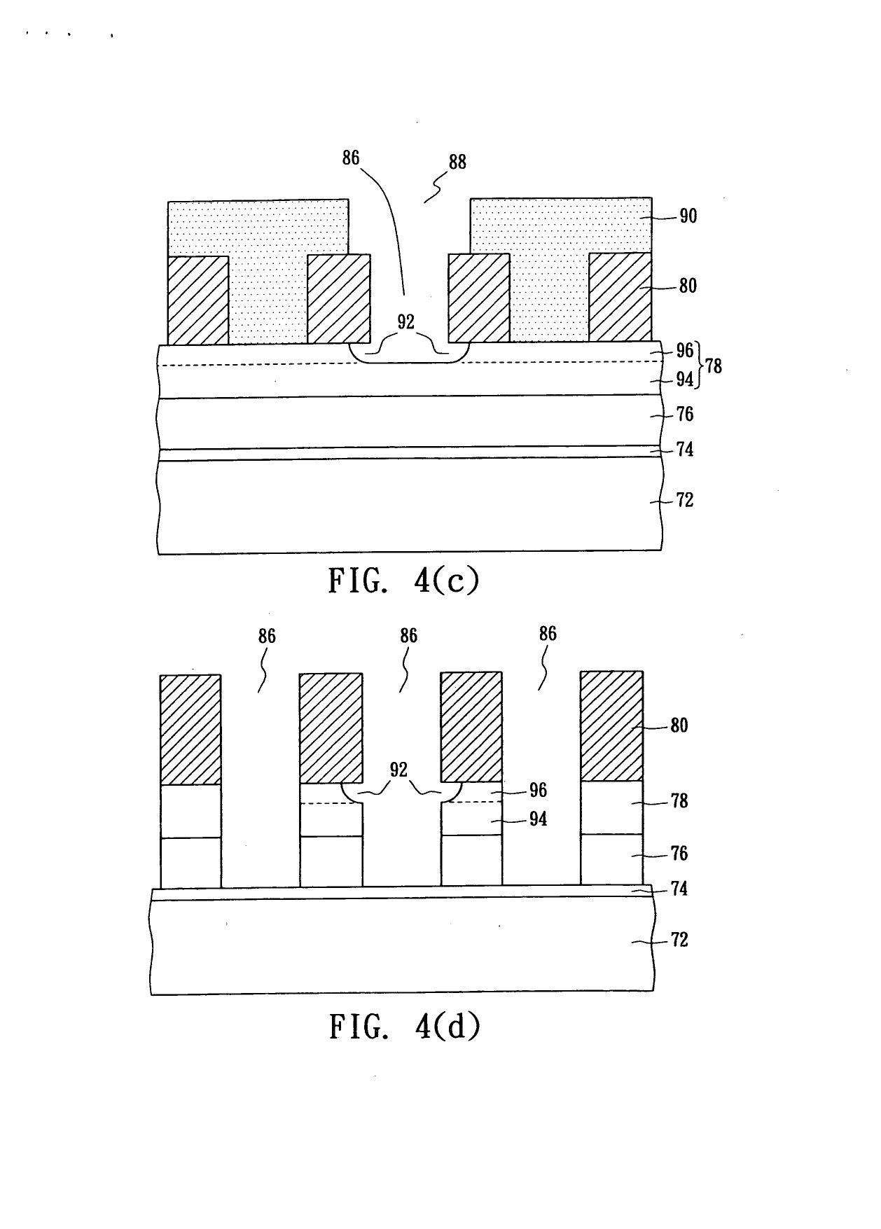

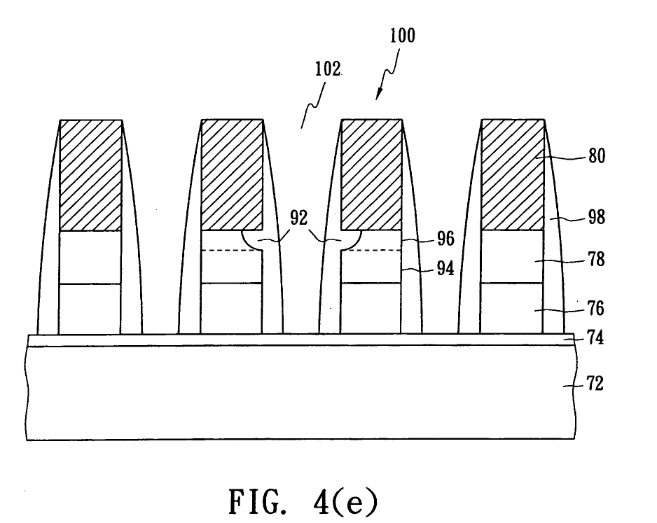

FIG. 4 (a) to FIG. 4(e) illustrate another method for preparing a semiconductor gate structure 100 according to the present invention. As shown in FIG. 4(a), the present invention first forms a gate dielectric layer 74, a first conductive layer 76, a second conductive layer 78 and an insulation layer 80 in sequence on a substrate 72. A photolithographic process is performed using the gate conductor mask 50 shown in FIG. 2(f) to form a photoresist layer 82 having a plurality of strip-shaped opening 82. An etching process is then performed to form a plurality of strip-shaped opening 86 in the insulation layer 80, and the photoresist layer 82 is removed subsequently, as shown in FIG. 4(b).

Referring to FIG. 4(c), a photoresist layer 90 is formed on the insulation layer 80, and a photolithographic process is performed using the bit-line contact window mask 40 shown in FIG. 2(b) to form an opening 88 in the photoresist layer 90. The second conductive layer 78 can be divided into a top portion 96 and a bottom portion 94. An etching process is performed to form a concave 92 in the top portion 96 of the second conductive layer 78, wherein the etching process to form the concave 92 is the same as that to form the concave 34 described before. After the photoresist layer 90 is removed, an etching process is performed to removed a portion of the first conductive layer 76 and the second conductive layer 78 below the strip-shaped opening 86, as shown in FIG. 4(d).

Referring to FIG. 4(e), a spacer 98 is formed on sidewalls of the first conductive layer 76, the second conductive layer 78 and the insulation layer 80 to complete the semiconductor gate structure 100, wherein the concave 92 is filled with an insulation material of the spacer 98. The position of the concave 92 is defined by the bit-line contact window mask 40, and the opening between two concaves 92 is a bit-line contact window 102. Since the concave 92 at the top portion 96 of the second conductive layer 78 increases the distance between the second conductive layer 78 and a contact metal subsequently formed in the bit-line contact window 102, the short circuit originating from the electrical contact between the second conductive layer 78 and the contact metal in the bit-line contact window 102 can be avoided. In addition, since the concave 92 is formed only at a region where the second conductive layer 78 approximates the bit-line contact metal, the resistance of the semiconductor structure 100 does not be increased dramatically so that the electrical property is kept.

In short, the present invention forms the concave only at a region where the second conductive layer approximates the bit-line contact window, while the gate conductor keeps the original strip-shaped profile at the other region. Consequently, the occurrence of the short circuit originating from the electrical contact between the second conductive layer and the bit-line contact metal can be avoided, and the present invention also solves the issue of the dramatic increase of the resistance due to the full-scale shrink of the lateral width of the gate conductor.

The above-described embodiments of the present invention are intended to be illustrative only. Numerous alternative embodiments may be devised by those skilled in the art without departing from the scope of the following claims.

What is claimed is:

1. A semiconductor gate structure, comprising:
a substrate;
a gate dielectric layer positioned on the substrate;
a first conductive layer positioned on the gate dielectric layer; and
a second conductive layer, comprising:
a bottom portion positioned on the first conductive layer; and
a top portion positioned on the bottom portion, wherein one side of the top portion is aligned with one side of the bottom portion, and the top portion includes at least one concave on the other side.

2. The semiconductor gate structure of claim 1, wherein the width of the bottom portion is equal to the width of the first conductive layer.

3. The semiconductor gate structure of claim 1, wherein the top portion includes a plurality of discontinuous concaves.

4. The semiconductor gate structure of claim 3, wherein a constant distance separates the plurality of concaves.

5. The semiconductor gate structure of claim 3, wherein a bit-line contact metal is positioned on the side of the concave.

6. The semiconductor gate structure of claim 1, wherein the first conductive layer and the second conductive layer are strip-shaped, and the top portion of the second conductive layer includes a plurality of concaves.

7. The semiconductor gate structure of claim 1, further comprising an insulation layer positioned on the second conductive layer, wherein the concave is filled up with an insulation material employed for the insulation layer.

8. The semiconductor gate structure of claim 1, further comprising a spacer positioned on sidewalls of the first conductive layer and the second conductive layer, wherein the concave is filled up with an insulation material employed for the spacer.

9. The semiconductor gate structure of claim 1, wherein the first conductive layer is made of polysilicon.

10. The semiconductor gate structure of claim 1, wherein the second conductive layer is made of tungsten silicide.

11. A method for preparing a semiconductor gate structure, comprising steps of:
forming a gate dielectric layer on a substrate;
forming a first conductive layer on the gate dielectric layer;
forming a second conductive layer on the first conductive layer;
forming a photoresist layer on the second conductive layer;
performing a photolithographic process to form at least one opening in the photoresist layer; and
performing an etching process to form at least one concave in a top portion of the second conductive layer below the opening.

12. The method for preparing a semiconductor gate structure of claim 11, wherein the etching process is a wet etching process using an etching solution including ammonia, hydrogen peroxide and water.

13. The method for preparing a semiconductor gate structure of claim 12, wherein the etching process is performed at a temperature between 60° C. and 70° C.

14. The method for preparing a semiconductor gate structure of claim 11, wherein the etching process is a dry etching process using an etching gas selected from the group consisting of carbon tetrafluoride and sulfur hexafluoride.

15. The method for preparing a semiconductor gate structure of claim 11, wherein the photolithographic process comprises using a bit-line contact mask.

16. A method for preparing a semiconductor gate structure, comprising steps of:
forming a gate dielectric layer on a substrate;
forming a first conductive layer on the gate dielectric layer;
forming a second conductive layer on the first conductive layer;
forming an insulation layer having a plurality of strip-shaped openings on the second conductive layer;
forming a photoresist layer on the insulation layer;
performing a photolithographic process to form at least one opening in the photoresist layer; and
performing a first etching process to form at least one concave in a top portion of the second conductive layer below the opening in the photoresist layer.

17. The method for preparing a semiconductor gate structure of claim 16, further comprising steps of:
removing the photoresist layer;
performing a second etching process to remove the first conductive layer and the second conductive layer below the strip-shaped openings; and
forming a spacer on sidewalls of the first conductive layer, the second conductive layer and the insulation layer, wherein the concave is filled up with an insulation material employed for the spacer.

18. The method for preparing a semiconductor gate structure of claim 16, wherein the first etching process is a wet etching process using an etching solution including ammonia, hydrogen peroxide and water.

19. The method for preparing a semiconductor gate structure of claim 18, wherein the first etching process is performed at a temperature between 60° C. and 70° C.

20. The method for preparing a semiconductor gate structure of claim 16, wherein the first etching process is a dry etching process using an etching gas selected from the group consisting of carbon tetrafluoride and sulfur hexafluoride.

21. The method for preparing a semiconductor gate structure of claim 16, wherein the photolithographic process comprises using a bit-line contact mask.
